(19) United States
(12) Patent Application Publication
(10) Pub. No.: US 2025/0098235 A1
(43) Pub. Date: Mar. 20, 2025

(54) SEMICONDUCTOR DEVICE AND METHOD FOR MANUFACTURING SAME

(71) Applicant: Microchip Technology Incorporated, Chandler, AZ (US)

(72) Inventors: Moaniss Zitouni, Gilbert, AZ (US); Zhiming Feng, Milpitas, CA (US); Bruno Villard, Aix en Provence (FR); Alain Chan, Hong Kong (CN); Xinyuan Dou, Fremont, CA (US); Eleonore Daemen, Trets (FR); Elsa Hugonnard-Bruyere, Fuveau (FR)

(73) Assignee: Microchip Technology Incorporated, Chandler, AZ (US)

(21) Appl. No.: 18/826,614

(22) Filed: Sep. 6, 2024

Related U.S. Application Data
(60) Provisional application No. 63/539,261, filed on Sep. 19, 2023.

(51) Int. Cl. H01L 29/06; H01L 21/265; H01L 29/66; H01L 29/78

(52) U.S. Cl. CPC H10D 62/109; H01L 21/26513; H10D 30/0281; H10D 30/65

(57) ABSTRACT

A method of manufacturing a lateral diffusion metal oxide semiconductor device. The method may include forming a high voltage deep N-well within a substrate, forming a high voltage N-well within the substrate, wherein the high voltage N-well is electrically coupled to the high voltage deep N-well, forming a drain terminal electrically coupled to the high voltage N-well, forming a source terminal, and forming a gate terminal disposed between the source terminal and the drain terminal. At least one of the high voltage N-well and the high voltage deep N-well may extend less than 2.0 microns beyond the drain terminal in a direction opposite from the source terminal.

### CROSS-REFERENCE TO RELATED APPLICATION

The present application claims priority to U.S. Provisional Patent Application No. 63/539,261, filed on Sep. 19, 2023, the contents of which are hereby incorporated by reference in their entirety.

### TECHNICAL FIELD

The present disclosure relates generally to semiconductor devices, and more specifically to lateral diffusion metal oxide semiconductor (LDMOS) devices and methods for manufacturing same to reduce impact ionization and current crowding while maintaining breakdown voltage.

### SUMMARY

According to an aspect of one or more examples, there is provided a semiconductor device. The semiconductor device may include a substrate, a high voltage deep N-well formed within the substrate, a high voltage N-well formed within the substrate and electrically coupled to the high voltage deep N-well, a drain terminal electrically coupled to the high voltage N-well, a source terminal, and a gate terminal disposed between the source terminal and the drain terminal, wherein at least one of the high voltage N-well and the high voltage deep N-well extends less than 2.0 microns beyond the drain terminal in a direction opposite from the source terminal. The high voltage deep N-well may be offset by 0.25 microns to 0.5 microns with respect to the high voltage N-well. An end of the high voltage deep N-well may be laterally closer to a substrate tie of the high voltage deep N-well than an end of the high voltage N-well to the drain terminal. The semiconductor device may comprise a shallow trench isolation layer extending from the gate terminal to the high voltage N-well. The semiconductor device may comprise a p-well implant extending from the gate terminal to the high voltage deep N-well. The p-well implant may comprise a 5-volt p-well implant. The semiconductor device may comprise an accumulation region extending laterally between the P-well beneath the gate terminal to the shallow trench isolation layer.

According to another aspect of one or more examples, there is provided a method of manufacturing a semiconductor device. The method may include forming a high voltage deep N-well within a substrate, forming a high voltage N-well within the substrate, wherein the high voltage N-well is electrically coupled to the high voltage deep N-well, forming a drain terminal electrically coupled to the high voltage N-well, forming a source terminal, and forming a gate terminal disposed between the source terminal and the drain terminal. At least one of the high voltage N-well and the high voltage deep N-well may extend less than 2.0 microns beyond the drain terminal in a direction opposite from the source terminal. The high voltage deep N-well may be offset by 0.5 microns with respect to the high voltage N-well. An end of the high voltage deep N-well may laterally closer to a substrate tie of the high voltage deep N-well than an end of the high voltage N-well to the drain terminal. The method may comprise forming a shallow trench isolation layer extending from the gate terminal to the high voltage N-well. The method may comprise forming a p-well implant extending from the gate terminal to the high voltage deep N-well. The p-well implant may comprise a 5-volt p-well implant. The method may comprise forming an accumulation region extending laterally between the P-well beneath the gate terminal to the shallow trench isolation layer.

### BRIEF DESCRIPTION OF DRAWINGS

FIG. 1 shows a laterally diffused metal oxide semiconductor (LDMOS) device according one or more examples.

FIG. 2 shows a graph illustrating how the breakdown voltage BVdss changes as a function of the high voltage N-well extension for multiple high voltage N-well-high voltage deep N-well offsets according to one or more examples.

FIG. 3A shows a laterally diffused metal oxide semiconductor (LDMOS) device according one or more examples.

FIG. 3B shows a laterally diffused metal oxide semiconductor (LDMOS) device according one or more examples.

FIGS. 4A-4B show two graphs illustrating how the high voltage N-well/high voltage deep N-well extension from the drain terminal effects the breakdown voltage BVdss, and how the drain current Ids varies in response to the drain source voltage Vds at multiple different high voltage N-well/high voltage deep N-well extensions according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

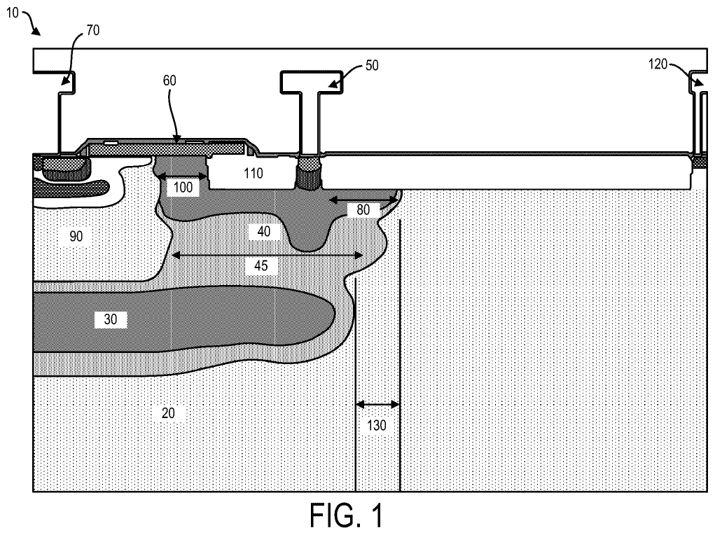

FIG. 1 shows a cut away view of a laterally diffused metal oxide semiconductor (LDMOS) device 10 according to one or more examples. The LDMOS device 10 of FIG. 1 may include a high voltage deep N-well 30 implant that functions to isolate the LDMOS device 10 from a substrate 20. The high voltage deep N-well 30 has high energy around 3 MeV and a dose of around 2.5 e12. The LDMOS device 10 may include a high voltage N-well 40 implant that is electrically coupled to the high voltage deep N-well 30 to connect the high voltage deep N-well 30 to a drain terminal 50 located on top of the substrate 20, which drain terminal 50 may be made of silicon. The high voltage N-well is a combination of several shallow implants less than 400 KeV and a high dose implant of less than 2.0 e13. The high voltage N-well 40 may be used as part of the drain terminal 50 of the LDMOS device 10 or as part of the channel in the LDMOS device 10. The LDMOS device 10 may also include a gate terminal 60 and a source terminal 70 located on top of the substrate 20. At least one of the high voltage deep N-well 30 and/or the high voltage N-well 40 are formed within the substrate 20 and extend laterally less than 2.0 microns beyond the drain terminal 50 in a direction opposite from the source terminal 70. The high voltage N-well 40 is also formed within the substrate 20 has a lateral width 45 from under the gate terminal 60 to beyond the drain terminal 50. The amount by which the high voltage N-well 40 extends beyond the drain terminal 50 is referred to as the high voltage N-well extension 80 in FIG. 1. In other words, the portion of the lateral width 45 of the high voltage N-well 40 which extends beyond the drain terminal 50 is referred to as the high voltage N-well extension 80. A P-well 90, such as a 5-volt p-well, may be formed within the substrate 20, and the source terminal 70 may be formed above the P-well 90. The 5-Volt p-well is an implant used for CMOS logic area that may also be used for an LDMOS device 10. The 5-volt p-well may be used as a body/channel of the LDMOS device 10. The 5-volt p-well may also be used as a substrate tie and drain of the LDMOS device 10.

The high voltage N-well 40 may include an accumulation region 100 beneath the gate terminal 60. The accumulation region 100 may have a length that extends laterally between an end of the channel of the P-well 90 beneath the gate terminal 60 and a shallow trench isolation 110 layer. A narrow accumulation region 100 may result in a current crowding effect as well as high impact ionization and quasi-saturation at high drain-source voltage (Vds) and high gate-source voltage (Vgs). Increasing the accumulation region 100 may improve device performance by reducing the current crowding effect and high impact ionization, but may also reduce the breakdown voltage (BVdss).

According to one or more examples, as shown in FIG. 1, the high voltage N-well extension 80 may be dimensioned so that the high voltage N-well 40 extends laterally less than 2.0 microns beyond the drain terminal 50 in a direction opposite from the source terminal 70. As shown in the example of FIG. 1, the high voltage deep N-well 30 may be offset 130 by 0.25 microns to 0.5 microns, laterally, with respect to the high voltage N-well 40 such that the end of the high voltage deep N-well 30 extending in a direction opposite from the source terminal 70 is laterally closer to the drain terminal 50 than the end of the high voltage N-well 40 the direction opposite from the source terminal 70. In other words, an end of the high voltage deep N-well 30 closest to a substrate tie 120 in the example of FIG. 1 may be laterally closer to the drain terminal 50 than an end of the high voltage N-well 40 closest to the substrate tie 120.

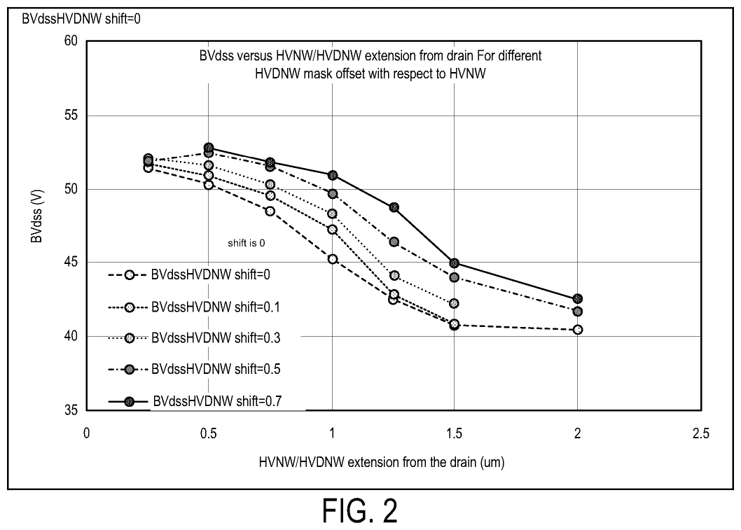

FIG. 2 shows a graph illustrating how the breakdown voltage BVdss changes as a function of the high voltage N-well extension 80 for multiple high voltage N-well/high voltage deep N-well offsets. As shown in FIG. 2, the bottom-most curve represents an example in which there is an offset 130 between the high voltage N-well and the high voltage deep N-well is zero, meaning that the high voltage N-well and the high voltage deep N-well extend approximately the same distance beyond the drain terminal. In this zero-offset example, the breakdown voltage BVdss increases from approximately 40 V when the high voltage N-well extension 80 is less than 2.0 microns to approximately 50 V when the high voltage N-well extension 80 is 0.5 microns. The four curves above the zero-offset curve represent offsets 130 of 0.1 microns, 0.3 microns, 0.5 microns, and 0.7 microns, respectively. As shown in FIG. 2, the breakdown voltage BVdss is generally greater as the high voltage N-well/high voltage deep N-well offset 130 increases. For example, the top-most curve represents a high voltage N-well-high voltage deep N-well offset 130 of 0.7 microns, and indicates a breakdown voltage of approximately 51 V when the high voltage N-well extension 80 is 1.0 micron, whereas the breakdown voltage is approximately 45 V when the high voltage N-well extension 80 is 1.0 micron for the example where the offset 130 is zero.

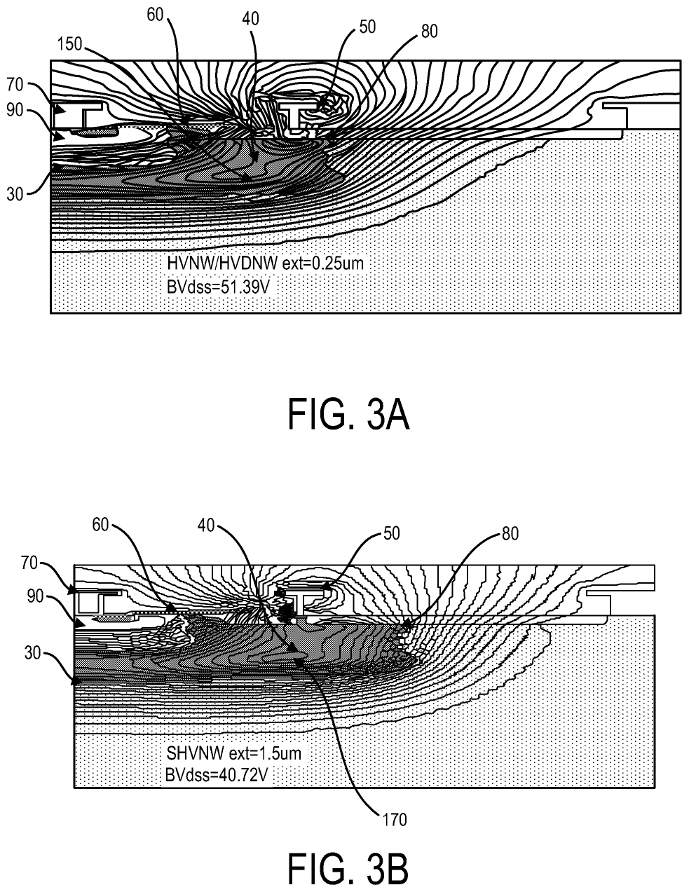

FIG. 3A shows a laterally diffused metal oxide semiconductor (LDMOS) device 10 according to one or more examples. Like the example of FIG. 1, the example of FIG. 3A includes a gate terminal 60, source terminal 70, a drain terminal 50, a high voltage deep N-well 30, a high voltage N-well 40 having a high voltage N-well extension 80 that extends beyond the drain terminal 50, and a P-well 90. Unlike the example of FIG. 1, the example of FIG. 3A shows an offset of 0.25 microns between the high voltage N-well 40 and the high voltage deep N-well 30.

FIG. 3B shows a laterally diffused metal oxide semiconductor (LDMOS) device 10 according to one or more examples. Like the example of FIG. 3A, the example of FIG. 3B includes a gate terminal 60, source terminal 70, a drain terminal 50, a high voltage deep N-well 30, a high voltage N-well 40 having a high voltage N-well extension 80 that extends beyond the drain terminal 50, and a P-well 90.

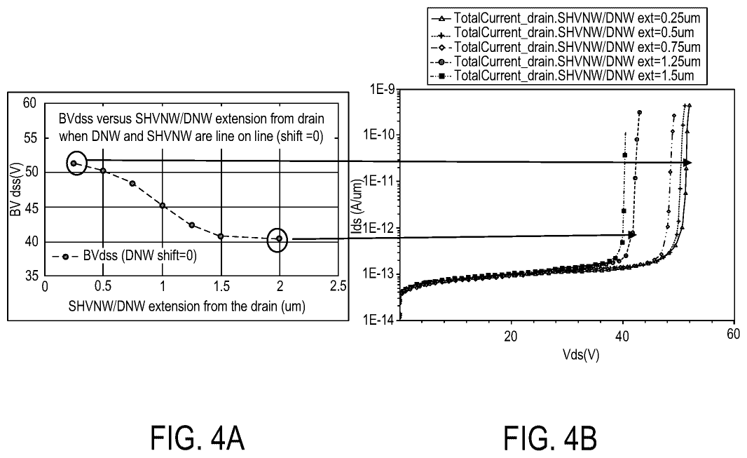

The graph of FIG. 4A shows multiple Ids-Vds curves for various high voltage N-well/high voltage deep N-well extensions. As shown in the graph of FIG. 4B, the drain current Ids increases rapidly at lower drain source voltages Vds when the high voltage N-well/high voltage deep N-well extensions are larger (e.g., 1.5 microns), and increases at higher drain source voltages Vds when the high voltage N-well/high voltage deep N-well extensions are smaller (e.g., 0.25 microns). According to one or more examples, the high voltage N-well extension may be less than 2 microns beyond the drain terminal, and the high voltage deep N-well may be offset from the high voltage N-well such that the high voltage N-well extends beyond the drain terminal by a greater distance that the high voltage deep N-well extends beyond the drain terminal.

The laterally diffused metal oxide semiconductor (LDMOS) device may be fabricated according to one or more examples. A high voltage deep N-well may be implanted into a substrate. A high voltage N-well may be implanted into the substrate. A drain terminal may be formed on a top surface of the substrate that is electrically coupled to the high voltage deep N-well. A source terminal may be formed on the top surface of the substrate. A gate terminal may be formed on the top surface of the substrate and disposed between the source terminal and the drain terminal. At least one of the high voltage deep N-well and/or the high voltage N-well may extend less than 2.0 microns beyond the drain terminal in a direction opposite from the source terminal. The high voltage N-well is also formed within the substrate and extends from under the gate terminal to beyond the drain terminal. The amount by which the high voltage N-well extends beyond the drain terminal is referred to as the high voltage N-well extension. A P-well, such as a 5-volt p-well, may be formed within the substrate, and the source terminal may be formed above the P-well. The high voltage N-well may include an accumulation region beneath the gate terminal, which may have an accumulation region length that extends between an end of the channel (this channel is shown as P-well 90 in FIG. 1 and FIGS. 3A-3B) beneath the gate terminal and a shallow trench isolation layer. A narrow accumulation region length may result in a current crowding effect as well as high impact ionization and quasi-saturation at high drain-source voltage (Vds) and high gate-source voltage (Vgs). Increasing the accumulation region length parameter may improve device performance by reducing the current crowding effect and high impact ionization, but may also reduce the breakdown voltage (BVdss). The high voltage deep N-well may be offset by 0.25 microns to 0.5 microns with respect to the high voltage N-well such that the end of the high voltage deep N-well is laterally closer to the drain terminal than the lateral end of the high voltage N-well. In other words, an end closest to a substrate tie of the high voltage deep N-well may laterally be closer to the drain terminal than an end closest to the substrate tie of the high voltage N-well.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A semiconductor device comprising:
a substrate;
a high voltage deep N-well formed within the substrate;
a high voltage N-well formed within the substrate and electrically coupled to the high voltage deep N-well;
a drain terminal electrically coupled to the high voltage N-well;
a source terminal; and
a gate terminal disposed between the source terminal and the drain terminal;
wherein at least one of the high voltage N-well and the high voltage deep N-well extends less than 2.0 microns beyond the drain terminal in a direction opposite from the source terminal.

2. The semiconductor device of claim 1, wherein the high voltage N-well and the high voltage deep N-well extend less than 2.0 microns beyond the drain terminal in a direction opposite from the source terminal.

3. The semiconductor device of claim 1, wherein the high voltage deep N-well is laterally offset by less than 0.5 microns with respect to the high voltage N-well.

4. The semiconductor device of claim 3, wherein an end of the high voltage deep N-well is laterally closer to a substrate tie of the high voltage deep N-well than an end of the high voltage N-well to the drain terminal.

5. The semiconductor device of claim 1 comprises a shallow trench isolation layer extending from the gate terminal to the high voltage N-well.

6. The semiconductor device of claim 1 comprises a p-well implant extending from the gate terminal to the high voltage deep N-well.

7. The semiconductor device of claim 6 comprises an accumulation region extending laterally between the P-well beneath the gate terminal to the shallow trench isolation layer.

8. The semiconductor device of claim 6 wherein the p-well implant comprises a 5-volt p-well implant.

9. A method of manufacturing a semiconductor device, the method comprising:
forming a high voltage deep N-well within a substrate;
forming a high voltage N-well within the substrate, wherein the high voltage N-well is electrically coupled to the high voltage deep N-well;
forming a drain terminal electrically coupled to the high voltage N-well;
forming a source terminal; and
forming a gate terminal disposed between the source terminal and the drain terminal;
wherein at least one of the high voltage N-well and the high voltage deep N-well extend less than 2.0 microns beyond the drain terminal in a direction opposite from the source terminal.

10. The method of claim 9, wherein the high voltage N-well and the high voltage deep N-well extend less than 2.0 microns beyond the drain terminal in a direction opposite from the source terminal.

11. The method of claim 9, wherein the high voltage deep N-well is offset by less than 0.5 microns with respect to the high voltage N-well.

12. The method of claim 11, wherein an end of the high voltage deep N-well is laterally closer to a substrate tie of the high voltage deep N-well than an end of the high voltage N-well to the drain terminal.

13. The method of claim 9 comprises forming a shallow trench isolation layer extending from the gate terminal to the high voltage N-well.

14. The method of claim 9 comprises forming a p-well implant extending from the gate terminal to the high voltage deep N-well.

15. The method of claim 14 comprises forming an accumulation region extending laterally between the P-well beneath the gate terminal to the shallow trench isolation layer.

16. The method of claim 14 wherein the p-well implant comprises a 5-volt p-well implant.
